(19) United States
(12) Patent Application Publication
(10) Pub. No.: US 2008/0160714 A1
(43) Pub. Date: Jul. 3, 2008

(54) METHOD OF FORMING SEMICONDUCTOR DEVICE

(75) Inventors: Cheon Man SHIM, Seoul (KR); Ji Ho HONG, Hwaseong-si (KR); Sang Chul KIM, Seoul (KR); Haeng Leem JEON, Anyang-si (KR)

Correspondence Address: WORKMAN NYDEGGER, 60 EAST SOUTH TEMPLE, 1000 EAGLE GATE TOWER, SALT LAKE CITY, UT, 84111, US

(73) Assignee: DONGBU HITEK CO., LTD., Seoul (KR)

(21) Appl. No.: 11/944,231

(22) Filed: Nov. 21, 2007

(30) Foreign Application Priority Data
Dec. 29, 2006 (KR) 10-2006-0137334

(51) Int. Cl. H01L 21/68

(52) U.S. Cl. 438/401; 257/E21.536

(57) ABSTRACT

A method for forming a semiconductor device comprising forming an inter-layer dielectric (ILD) layer on a semiconductor substrate; forming a first trench and second trench in a cell area on the ILD layer, wherein the second trench has a width which is wider than the first trench; forming a first metal layer on the substrate, such that the first metal layer fills the first trench and does not entirely fill the second trench; performing a planarization process on the first metal layer such that the surface of the first metal layer in the first trench and the surface of the substrate has a height which is different than the height of the surface of the first metal layer in the second trench; and forming a plurality of align key and overlay key areas by forming a second metal layer on the surface of the substrate and first metal layer.

### CROSS-REFERENCES AND RELATED APPLICATIONS

This application claims the benefit of Korean Patent Application No. 10-2006-0137334, filed on Dec. 29, 2006, which is hereby incorporated by reference in its entirety.

### BACKGROUND OF THE INVENTION

1. Field of the Invention

The present invention relates to a method for forming a semiconductor device. More particularly, the present invention relates to a method for forming a semiconductor device capable of reducing the process of forming align key and overlay key areas.

2. Discussion of the Related Art

In order form a semiconductor device, many photolithography processes are typically performed. During each photolithography process, an aligning process is used to align the semiconductor substrate wherein the alignment is precisely measured and corrected prior to the etching process of the photolithography process. By properly aligning the semiconductor, the problem of misalignment between layers may be minimized.

During the aligning processes an align key and an overlay key are arranged in a predetermined area on the semiconductor substrate. The align key is used to align a photo mask on the semiconductor for use during the exposure process of a photolithography process, and the overlay key is used to measure whether photo mask patterns accurately overlapped on the semiconductor substrate. Typically, the align key and overlay key are formed as a structure with a surface and a step in an area referred to as a scribe lane that is located between the main chips.

In devices where the metal wiring is formed using a copper process in a semiconductor device of 1.13 μm or less, the wire bonding of the copper layer strong and the copper layer is easily oxidized. Thus, the copper layer it is used as a pad by depositing an aluminum layer on the copper layer.

FIGS. 1A to 1D are cross-sectional views for explaining a method for forming a semiconductor device according to the related art.

As shown in FIG. 1A, an interlayer dielectric (ILD) layer 103 is formed on a semiconductor substrate 102 including a cell area 100 and a scribe lane area 101, in order to form trenches 104 and 105 on the ILD layer 103. Then, a photo resist pattern is formed by coating the ILD layer with a photo resist material in a predetermined pattern.

Next, an etching process is performed using the photo resist pattern in order to form a trench 105 in the scribe lane area 101 which is wider than the trench 104 of the cell area 100. Then ashing and cleaning processes are performed to remove the photo resist pattern.

As shown in FIGS. 1B and 1C, a copper layer 106 is deposited over the semiconductor substrate 102 including the area within the trenches 104 and 105 using an electroplating method to fill the trenches 104 and 105. Next, a planarization process is performed on the copper layer 106 using a chemical mechanical polishing (CMP) method so as to form the copper layer pattern 106a. Then, as shown in FIG. 1D, an aluminum layer 107 is deposited on the copper layer pattern 106a using a damascene method in order to form a semiconductor device known in the art.

However, as shown in FIGS. 2A and 2B, one difficulty in the semiconductor process known in the art is that since there is no difference in height between the copper layer pattern 106a and the aluminum layer pattern 107 in the scribe lane area 101, it is difficult to properly align the patterns used during the photolithography processes.

### BRIEF SUMMARY OF THE INVENTION

The present invention proposes to solve the problem of the related art. It is an object of the present invention to provide a method for forming a semiconductor device capable of simplifying the process of forming align key and overlay key areas.

In order to accomplish this object, one aspect of the invention is a method for forming a semiconductor device comprising forming an inter-layer dielectric (ILD) layer on a semiconductor substrate, forming a first trench or a via on the ILD layer in a cell area, forming a second trench with a width which is wider than the first trench, depositing a first metal layer on the semiconductor substrate including the area within first trench and the second trench, such that the first metal layer completely fills the first trench but does not completely fill the second trench, performing a planarization process on the first metal layer such that the surface of the first metal layer in the first trench and the surface of the substrate has a height different than the surface of the first metal layer in the second trench, and forming a plurality of align key and overlay key areas by forming a second metal layer on the surface of the substrate and first metal layer which utilize the difference in height between the surface the substrate and first metal layer in the first trench and the first metal layer in the second trench.

### BRIEF DESCRIPTION OF THE DRAWINGS

The accompanying drawings, which are included to provide a further understanding of the invention, are incorporated in and constitute a part of this application. The drawings illustrate embodiment(s) of the invention and together with the description serve to explain the principle of the invention. In the drawings:

FIGS. 1A to 1D are cross-sectional views illustrating a method for forming a semiconductor device known in the related art;

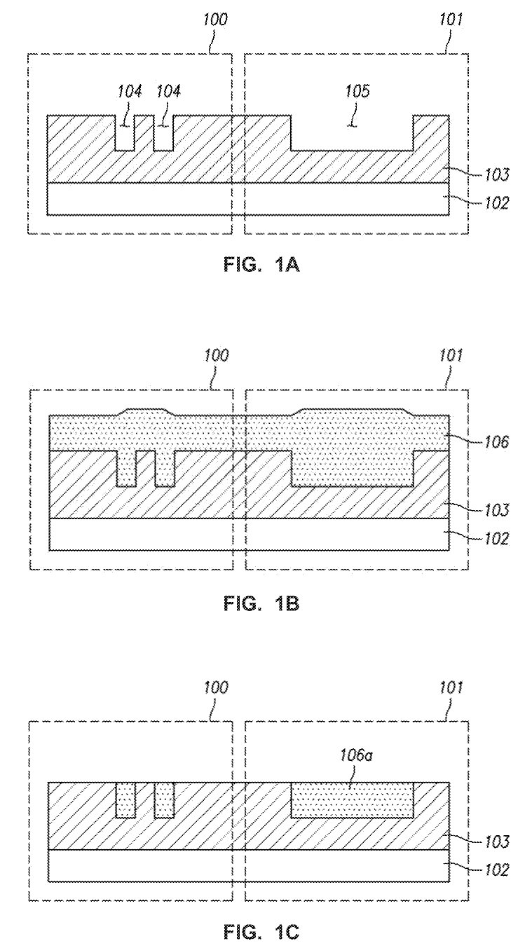

FIGS. 2A to 2B are focused ion beam (FIB) photographs illustrating a cell area and a scribe lane area of a semiconductor device known in the art;

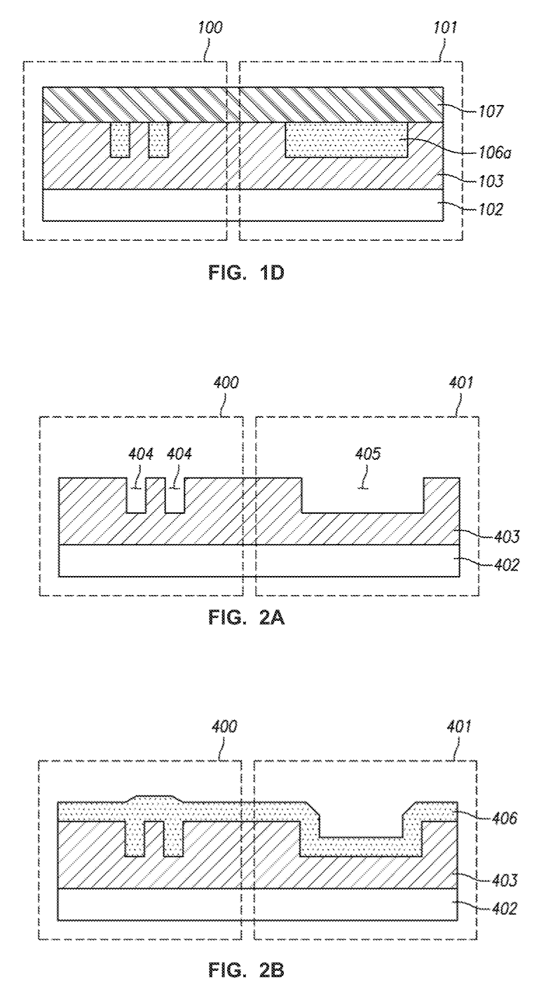

FIG. 3 is an optical photograph illustrating a scribe lane area of a semiconductor device known in the art;

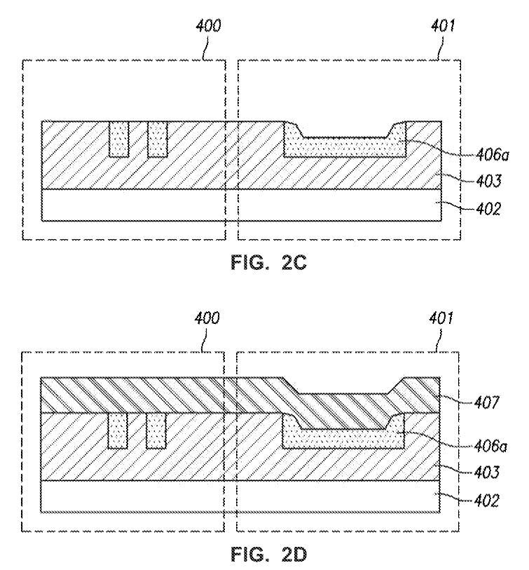

FIGS. 4A to 4D are cross-sectional views illustrating a method for forming a semiconductor device according to the present invention;

FIGS. 5A and 5B are focused ion beam (FIB) photographs illustrating the trench pattern of the cell area of the semiconductor device of the present invention;

FIGS. 6A and 6B are FIB photographs the via pattern of the cell area of the semiconductor device of the present invention; and

FIGS. 7A and 7B are optical photographs illustrating a scribe lane area of the semiconductor device of the present invention.

### DETAILED DESCRIPTION OF THE INVENTION

Hereinafter, a method for forming a semiconductor device according to the present invention will be described with reference to the accompanying drawings.

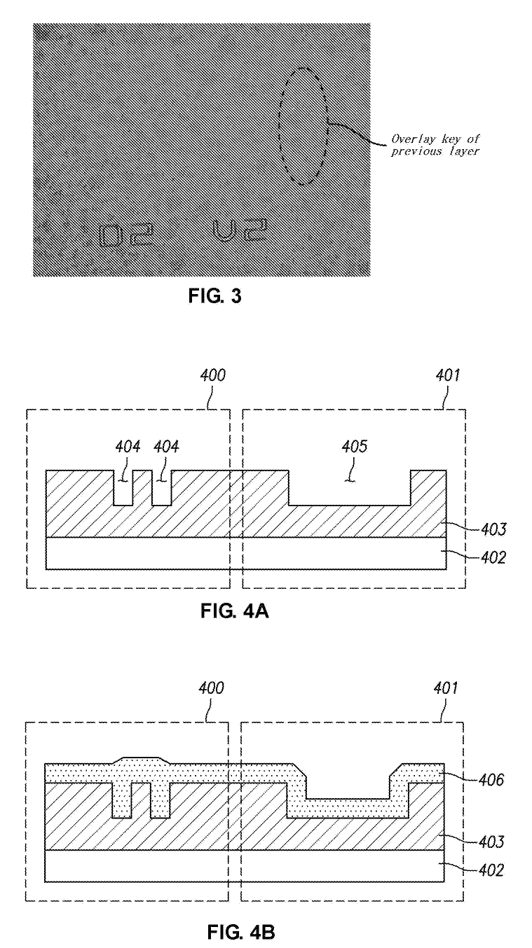

FIGS. 4A to 4D are cross-sectional views illustrating a method for forming a semiconductor device according to the present invention.

As shown in FIG. 4A, an inter-layer dielectric (ILD) layer 403 is formed on a semiconductor substrate 402 including a cell area 400 or a scribe lane area 401 so as to form at least one trench on the ILD layer 403. The trenches are formed by forming a photo resist pattern by coating a photoresist material and then forming it into a pattern.

Thereafter, an etching process is performed using the photo resist pattern as a mask so as to form a trench 405 in the scribe lane 401 with a width which is wider than the trench 404 of the cell area 400. Then ashing and cleaning processes are performed to remove the photo resist pattern.

Preferably, the trench 404 of the cell area 400 is formed with a width of between 0.1 and 0.5 μm, and the trench 405 of the scribe lane area 401 is formed with a width of between 1 and 10 μm.

As shown in FIGS. 4B and 4C, a first metal layer 406 is deposited over the semiconductor substrate 402, including over the area within the trenches 404 and 405 of the cell area 400 and scribe lane areas 401 using an electroplating (EP) method, such that the trench 404 of the cell area 400 is completely filled with the first metal layer 406. After the trench 404 of the cell area 400 is filled, the depositing process stops and a planarization process is performed on the first metal layer 406 using a chemical mechanical polishing (CMP) method. Because the trench 405 in the scribe area 401 is wider than the trench 404 in the cell area, when the depositing process stops after filling the smaller trench 404, the first metal layer 406 does not completely fill the area within the trench 405 in the scribe area 401. Thus, the height of the surface of the first metal layer pattern 406a in the scribe lane area 401 is less than the height of the surface of the substrate and first metal layer 406 in the trench 404 in the cell area.

Herein, the first metal layer 406 can be formed of various metals, including copper (Cu), silver(Ag), and aluminum (Al).

Thus, the trench 405 of the scribe lane area 401 is only partially filled with the first metal layer 406 since it has a wider width than the trench 404 of the cell area 400.

Next, as shown in FIG. 4D, a second metal layer 407, formed of a material such as aluminum (Al), is deposited over the semiconductor substrate 402 including the area within the trenches 404 and 405.

Herein, the second metal layer 407 in the trench 405 of the scribe lane area 401 is formed on top of the first metal layer pattern 406a, meaning that the height of the surface of the second metal layer 407 in the scribe lane area 401 is less than the height of the surface of the second metal layer 407 in the trench 404 in the cell area, making it possible to simplify the overlay and/or alignment process during the photolithography process.

Thus, because there is a difference in height in the surfaces formed in the first metal layer 405 and the second metal layer, it is possible to reduce the process forming the align and overlay key areas.

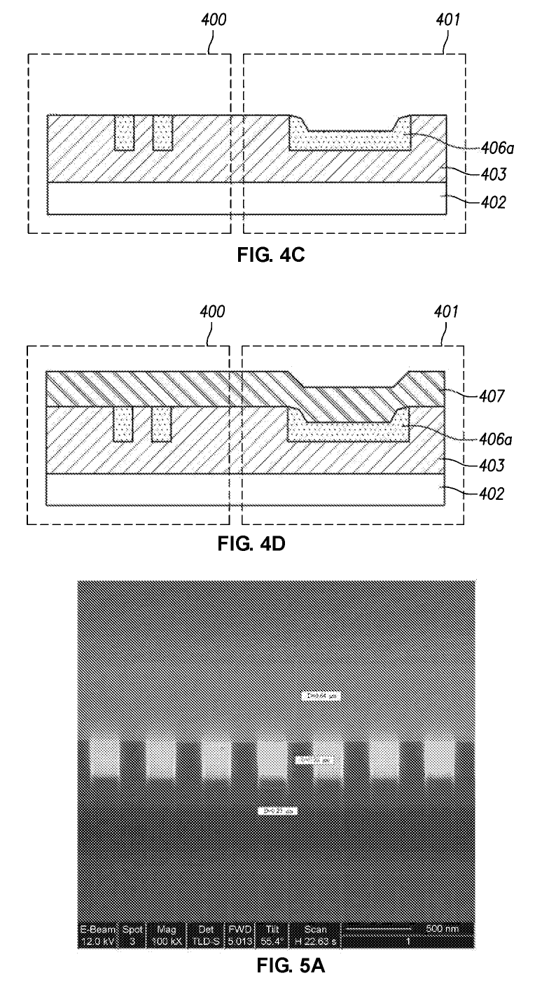

That is, as shown in FIG. 5A, the trench pattern of the cell area is filled with the first metal layer, and as shown in FIG. 5B, the first metal layer and the second metal layer in the trench of the scribe lane area are formed with surfaces that are different in height, which can be used during the trench process.

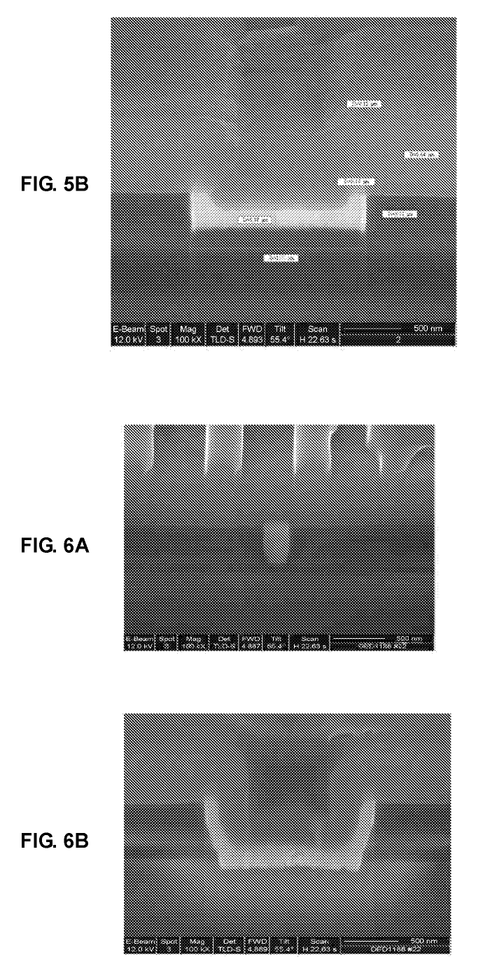

Also, as shown in FIG. 6A, the via pattern of the cell area is filled with the first metal layer. In contrast, as shown in FIG. 6B, it can be appreciated that the first metal layer and the second metal layer in the trench of the scribe lane area are formed with surfaces that are different in height, which can be used during the via process.

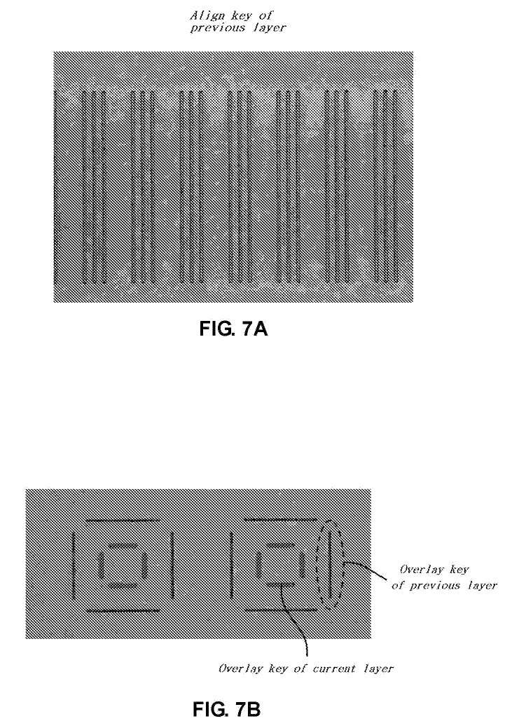

Therefore, as shown in FIGS. 7A and 7B, difference in height in the surfaces formed in the first metal layer and the second metal layer of the scribe lane area make it possible to confirm an align key of a previous layer, the overlay key of a previous layer, and the overlay key of a current layer.

The detailed description and specific examples, while indicating preferred embodiments of the present invention, are given by way of illustration only and not limitation. Various changes and modifications may be made without departing from the spirit and scope of the present invention, and the invention includes all such modifications.

Although a few embodiments of the present invention have been shown and described, it would be appreciated by those skilled in the art that changes may be made without departing from the principles and spirit of the invention, the scope of which is defined in the claims and their equivalents.

As described above, present invention relates to a method for forming a semiconductor device wherein a difference in height in the surface of the first metal layer and the second metal layer make it possible to perform an improved alignment process for the photolithography process.

In addition, the present invention can simplify the process of forming align key and overlay key areas in the scribe lane area.

What is claimed is:

1. A method for forming semiconductor device comprising the steps of:
forming an inter-layer dielectric (ILD) layer on a surface of a semiconductor substrate;
forming a first trench or a via on the ILD layer in a cell area;
forming a second trench on the ILD in a source area, the second trench having a width which is wider than the width of the first trench;
forming a first metal layer on the semiconductor substrate including the area within the first trench and the second trench, such that the first metal layer fills the first trench and does not entirely fill the second trench;
performing a planarization process on a surface of the first metal layer such that the surface of the first metal layer in the first trench and the surface of the substrate has a height different than the surface of the first metal layer in the second trench; and
forming a plurality of align key and overlay key areas by forming a second metal layer on the surface of the substrate and first metal layer which utilize the difference in height between the surface the substrate and first metal layer in the first trench and the first metal layer in the second trench.

2. The method according to claim 1, wherein the first trench or the via in the cell area is formed with a width of between 0.1 and 0.5 μm and the second trench is formed with a width of between 1 and 10 μm.

3. The method according to claim 1, wherein the first metal layer is formed of a material selected from the group of copper(Cu), silver(Ag), and aluminum (Al).

4. The method according to claim 4, wherein the second metal layer is formed such that the second metal layer does not entirely fill the second trench.

5. The method according to claim 5, wherein the second metal layer is formed of aluminum (Al).

6. A method for forming semiconductor device comprising the steps of:
forming an inter-layer dielectric (ILD) layer on a surface of a semiconductor substrate;
forming a first trench or a via on the ILD layer in a cell area with a width of between 0.1 and 0.5 μm;
forming a second trench on the ILD in a source area, the second trench having a width of between 1 and 10 μm;
forming a first metal layer on the semiconductor substrate including the area within the first trench and the second trench, such that the first metal layer fills the first trench and does not entirely fill the second trench;
performing a planarization process on a surface of the first metal layer such that the surface of the first metal layer in the first trench and the surface of the substrate has a height different than the surface of the first metal layer in the second trench;
forming a second metal layer on the surface of the semiconductor substrate and first metal layer; and
forming a plurality of align key and overlay key areas using the difference in height between the surface the substrate and first metal layer in the first trench and the first metal layer in the second trench.

8. The method according to claim 6, wherein the first metal layer is formed of a material selected from the group of copper(Cu), silver(Ag), and aluminum (Al).

9. The method according to claim 6, wherein the second metal layer is formed such that the second metal layer does not entirely fill the second trench.

10. The method according to claim 6, wherein the second metal layer is formed of aluminum (Al).
